(19) United States
(12) Patent Application Publication
(10) Pub. No.: US 2016/0119744 A1
(43) Pub. Date: Apr. 28, 2016

(54) METHOD FOR MONITORING PHOTOVOLTAIC POWER GENERATION USING RTU, AND WIRELESS RTU DEVICE THEREOF

(71) Applicant: HYMATICS, INC., Seongnam-si, Gyeonggi-do (KR)

(72) Inventor: Hyeong Seob YOON, Seoul (KR)

(21) Appl. No.: 14/896,208

(22) PCT Filed: May 9, 2014
(86) PCT No.: PCT/KR2014/004117

§ 371 Date: Dec. 4, 2015

(30) Foreign Application Priority Data
Jun. 10, 2013 (KR) 10-2013-0065780

(51) Int. Cl. H04W 4/00; H02S 50/00; G01R 19/25

(52) U.S. Cl. CPC H04W 4/008; G01R 19/2513; H02S 50/00

(57) ABSTRACT

The present invention provides a photovoltaic power generation monitoring method of a remote terminal unit (RTU), comprising: receiving photovoltaic power generation state information via a ZigBee communication from a photovoltaic inverter; measuring the power of a ZigBee wireless communication signal and determining whether the power belongs to a normal range; performing transmit power control and low-noise amplifier (LNA) control on the basis of the determination result; generating a remote message on the basis of the received photovoltaic power generation state information and verifying the remote message; and transmitting the remote message to a monitoring server via a Wi-Fi communication. Accordingly, the photovoltaic power generation monitoring method of the present invention enables monitoring of photovoltaic power generation facilities to be conducted smoothly.

### TECHNICAL FIELD

The present invention relates to a method for monitoring photovoltaic power generation using a remote terminal unit (RTU) and a wireless RTU device, and more particularly, to a method for monitoring photovoltaic power generation state wherein an RTU connected to the photovoltaic power plant measures and controls the power of a wireless transmission signal to smoothly conduct photovoltaic power generation monitoring.

### BACKGROUND ART

Photovoltaic power generation is a power generation scheme in which sunlight is converted into direct current (“DC”) electricity to generate power. In the photovoltaic power generation scheme, a solar light panel attached with a plurality of solar cells is extensively elongated to generate electricity using solar light energy.

Growing demand for renewable energy is leading to an increasing production of solar cells and solar cell arrays and to recent development of a grid-connected photovoltaic power generation system.

Further, a large number of nations including Australia, Germany, Israel, Japan, and the United States are supporting financial encouragement policies such as a mandatory purchase at standard price regulation and a price offset regulation which grant preferences to solar light electricity, thereby expanding the establishment of photovoltaic power generation facilities.

The photovoltaic power generation scheme is garnering attention as a future alternative energy source, in regard to being semi-permanent, simple in maintenance due to using solar cells, and using non-polluting, infinite solar energy.

However, although a conventional technique of detecting and controlling operation information of photovoltaic power generation facilities in a wireless manner has been developed, due to the absence of a function of measuring a transmission power range in a conventional ZigBee transmission device, it has been difficult to properly maintain the signal power range which is the target of regulation.

Accordingly, to ensure effective operation of an efficient photovoltaic power generation system, there is a need for an efficient monitoring method and a device with regard to photovoltaic power generation facilities.

### DISCLOSURE OF INVENTION

### Problem to be Solved by the Invention

One aspect of the present invention is conceived to satisfy the aforementioned needs in the conventional scheme, and addresses issues of an existing photovoltaic power generation device monitoring scheme, and the other aspect of the present invention provides a monitoring method that enables a wireless remote terminal unit (“RTU”) device to determine and control the range of transmission power, and the wireless RTU device related thereto.

### Means for Solving Problem

According to an aspect of the present invention, a method for monitoring photovoltaic power generation using remote terminal unit (RTU) comprises: receiving photovoltaic power generation state information via ZigBee wireless communications from a photovoltaic inverter; measuring the power of ZigBee wireless communications signals through which the photovoltaic power generation state information is received; determining whether the measured power is within a normal range; performing transmission power control and low-noise amplifier (LNA) control on the basis of the determination result; generating remote message on the basis of the received photovoltaic power generation state information; verifying the presence of errors in the generated remote message; and transmitting the generated remote message to a monitoring server via Wi-Fi communications in absence of the errors on the basis of the verification result.

According to another aspect of the present invention, a wireless remote terminal unit (RTU) device for monitoring photovoltaic power generation comprises: a ZigBee wireless communications unit for receiving photovoltaic power generation state information via ZigBee wireless communications from a photovoltaic inverter; a power measuring unit for measuring the power of ZigBee wireless communications signals through which the photovoltaic power generation state information is received; a measured power determining unit for determining whether the measured power is within a normal range; a controlling unit for performing transmission power control and low-noise amplifier (LNA) control on the basis of the determination result; a message generating unit for generating a remote message on the basis of the received photovoltaic power generation state information; a verifying unit for verifying the presence of errors in the generated remote message; and a Wi-Fi communications unit for transmitting the generated remote message to a monitoring server via Wi-Fi communications in absence of the errors on the basis of the verification result.

According to still another aspect of the present invention, a ZigBee wireless communications unit for receiving photovoltaic power generation state information via ZigBee wireless communications from a photovoltaic inverter; a power measuring unit for measuring the power of ZigBee wireless communications signals through which the photovoltaic power generation state information is received; a measured power determining unit for determining whether the measured power is within a normal range; a temperature sensor for reading an external temperature of the integrated ZigBee communications module; and an information transmitting unit for transmitting information output from the temperature sensor and the measured power determining unit to a wireless remote terminal unit (RTU).

### Effect of the Invention

Through the use of a photovoltaic power generation monitoring method and a monitoring system according to exemplary embodiments of the present invention, monitoring of a plurality of photovoltaic power plants may be achieved via a wireless communication. Thus, without environmental concerns, an efficient solution to the operation of monitoring information transmission equipment may be provided. In particular, transmit power may be uniformly maintained in the transmission of monitoring information.

### BRIEF DESCRIPTION OF DRAWINGS

FIG. 1 is a diagram illustrating a photovoltaic power generation monitoring system according to an exemplary embodiment;

FIG. 2 is a block diagram illustrating a configuration of a remote terminal unit (“RTU”) according to an exemplary embodiment;

FIG. 3 is a block diagram illustrating a configuration of a monitoring server according to an exemplary embodiment;

FIG. 4 is a flowchart illustrating a photovoltaic power generation monitoring method according to an exemplary embodiment;

FIG. 5 is a diagram illustrating a remote message according to an exemplary embodiment;

FIG. 6 is a diagram illustrating a configuration of a feedback message transmitted from a monitoring server to an RTU according to an exemplary embodiment; and

FIG. 7 is a diagram illustrating a configuration of a control message transmitted from a monitoring server to an RTU according to an exemplary embodiment.

### BEST MODE(S) FOR CARRYING OUT THE INVENTION

Exemplary embodiments will now be described more fully hereinafter with reference to the accompanying drawings. Further, the suffix for the components used in the description of “unit” and “device” are given merely in consideration of the easiness of writing this specification, and the “unit” and “device” can be used in combination thereof, and may be implemented using hardware components or software components.

Further, although the present invention can be modified in various manners and have several embodiments, exemplary embodiments are illustrated in the accompanying drawings and will be mainly described in the specification. However, the scope of the invention is not limited to the exemplary embodiments.

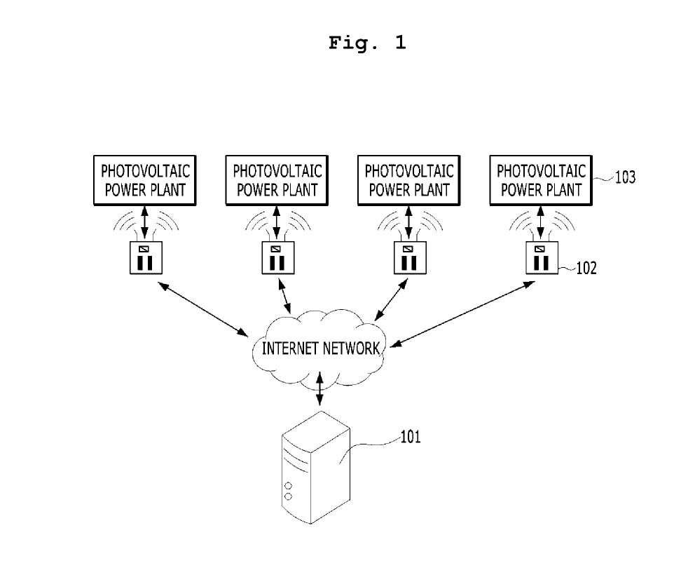

FIG. 1 is a diagram illustrating a photovoltaic power generation monitoring system according to an exemplary embodiment.

It refers to one of IEEE 802.15.4 standards which supports the local area communication. It is a technique for the local area communications in a range of about 10 meters (m) to about 20 m and ubiquitous computing in a wireless networking field such as home or office.

In other words, ZigBee is the concept of mobile phones or wireless local area network (“LAN”), and differs from a conventional technique in that ZigBee communicates a small quantity of information while significantly reducing power consumption.

ZigBee is utilized in the fields of an intelligent home network, a local area communications market such as buildings, industrial equipment automation, logistics, environment monitoring, a human interface, telematics, or military purposes. ZigBee is recently garnering attention as a ubiquitous establishment solution, such as a home network, due to being low in power consumption for its small size and low cost.

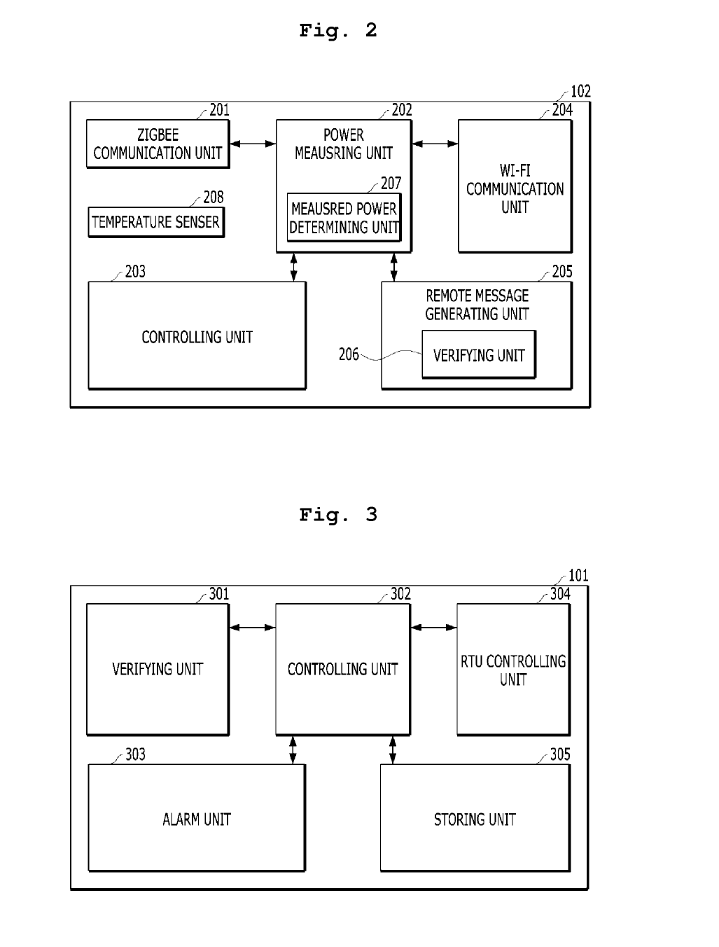

According to an exemplary embodiment, the photovoltaic power generation monitoring system may be configured as illustrated in FIG. 1. In other words, a plurality of remote terminal units (“RTU”) 102 may be connected to each of a plurality of photovoltaic power plants 103, and the plurality of RTUs 102 may be connected to a single monitoring server 101. In addition, the photovoltaic power plant 101 and the RTU may be wirelessly connected to one another via a ZigBee communication, and the RTU 102 and the monitoring server 101 may be connected to one another via an Internet communications using a Wi-Fi communications. The RTU 102 and the monitoring server 101 will be described in greater detail hereinafter with reference to FIGS. 2 and 3.

FIG. 2 is a block diagram illustrating a configuration of an RTU according to an exemplary embodiment.

The RTU 102 may include a ZigBee communications unit 201, a power measuring unit 202, a measured power determining unit 207, a Wi-Fi communications unit 204, a temperature sensor 208, a controlling unit 203, a remote message generating unit 205, and a verifying unit 206. The

ZigBee communications unit 201 may receive meter data from a photovoltaic power plant. In addition, according to embodiments, a first communications unit 201 may be the ZigBee communications unit. In other words, the first communications unit 201 may receive meter data from the photovoltaic power plant via a ZigBee communication. In addition, the ZigBee communications unit may receive meter data from each of a plurality of photovoltaic power plants.

The power measuring unit 202 may measure the power of a ZigBee wireless communications signal through which photovoltaic power generation state information is received, and the measured power determining unit 207 may determine whether the measured power belongs to a normal range.

The controlling unit 203 may perform transmit power control and low-noise amplifier (“LNA”) on the basis of the determination result. In other words, the controlling unit 203 may reduce power, or may adjust LNA at a connection portion at which power is not detected.

In addition, in a case in which the ZigBee communications with one of the plurality of photovoltaic inverters is not performed, the controlling unit 203 may control at least one of transmit power and LNA to determine whether the ZigBee communications that does not performed performs again, and more particularly, may switch an LNA ON/OFF state, and may determine, again, whether the ZigBee communications performs again.

The remote message generating unit 205 may generate a remote message on the basis of the received photovoltaic power generation state information. The remote message may include at least one of RTU register data, RTU sensor data, RTU wireless state data, and RTU photovoltaic power generation state data, and according to embodiments, may include all of RTU register data, RTU sensor data, RTU wireless state data, and RTU photovoltaic power generation state data.

The verifying unit 206 verifies a presence of an error in the generated remote message, and in a case in which the error is absent on the basis of the verification result, the Wi-Fi communications unit 204 transmits the generated remote message to the monitoring server via a Wi-Fi communication. In other words, the Wi-Fi communications unit 204 may transmit the generated remote message to the monitoring server via a Wi-Fi communication. In addition, the Wi-Fi communications unit may receive at least one of a feedback message and an RTU control message from the monitoring server.

The temperature sensor 208 may read external temperature of the RTU, and the message generating unit 205 may generate a remote message that performs temperature compensation for the received photovoltaic power generation state information on the basis of the read internal temperature of the RTU. In other words, read data in which a predetermined value is corrected in advance in the RTU may be transmitted to the monitoring server.

In addition, according to embodiments, the RTU may further include a third communications unit (not illustrated) that receives a user setting signal, and may transmit RTU setting information that is updated according to the user setting signal to the monitoring server via the Wi-Fi communications unit 204. A user may be connected to the RTU via the Internet, and may input a user setting signal to the RTU via the third communications unit. In addition, the user setting signal may be transmitted to the monitoring server to thereby update data associated with the RTU. In other words, the user setting signal may instantaneously reflect the demand of the user.

In addition, dissimilarly to the example illustrated in the drawings, according to another exemplary embodiment, an integrated ZigBee communications module may further include a power measuring unit and a temperature sensor. In other words, the integrated ZigBee communications module may include a ZigBee communications unit receiving photovoltaic power generation state information from a photovoltaic inverter via a ZigBee communication, a power measuring unit measuring the power of a ZigBee wireless communications signal through which photovoltaic power generation state information is received, a measured power determining unit determining whether the measured power belongs to a normal range, a temperature sensor reading an external temperature of the integrated ZigBee communications module, and an information transmitting unit transmitting information output from the temperature sensor and the measured power determining unit to a wireless RTU.

In addition, according to an exemplary embodiment, the measured power determining unit may include information associated with a predetermined normal range of power that is renewed according to an update signal input through a network.

FIG. 3 is a block diagram illustrating a configuration of a monitoring server according to an exemplary embodiment.

According to an exemplary embodiment, the monitoring server 101 may include a verifying unit 301, a controlling unit 302, an RTU controlling unit 304, an alarm unit 303, and a storing unit 305.

The verifying unit 301 may verify remote data transmitted via the RTU as illustrated in FIG. 2.

In addition, according to an exemplary embodiment, the verifying unit 301 may determine whether at least one of RTU register data, RTU sensor data, RTU wireless state data, and RTU photovoltaic power generation state data included in the remote data is in a normal state. In addition, according another exemplary embodiment, the verifying unit 301 may determine whether all of the RTU register data, RTU sensor data, RTU wireless state data, and RTU photovoltaic power generation state data included in the remote data is in a normal state.

The RTU controlling unit 304 may transmit an RTU control value to each of the RTUs on the basis of the verification result of the verifying unit 301. In addition, on the basis of the verification result of the verifying unit 301, in a case in which one of the RTUs is determined to be abnormal, the RTU controlling unit 304 may transmit a reset command to the abnormal RTU.

In a case in which the verifying unit 301 detects an abnormal value, the alarm unit 303 may set off an alarm. In addition, according to an exemplary embodiment, the alarm unit 303 may be connected to a mobile communications network, and may transmit a mobile alarm using a short message service (“SMS”) of a mobile communications network.

The storing unit 305 may store RTU data. In addition, the verifying unit may load the RTU data stored in the storing unit and may compare a value included in the remote data with the loaded RTU data, and in a case in which there is no non-matching value on the basis of the comparison result, may determine that the RTU is in a normal state. In addition, the storing unit may update the stored RTU data in a case in which a user setting signal is transmitted from the RTU. In addition, according to an exemplary embodiment, the storing unit 305 may include a plurality of data blocks in which RTU data associated with each of a plurality of RTUs is stored.

In a case in which remote controlling of the RTU can be performed, the controlling unit 302 may control the RTU controlling unit to transmit a control value, and in a case in which a mobile alarm is required, may control the alarm unit to transmit a mobile alarm to an external device through the alarm unit.

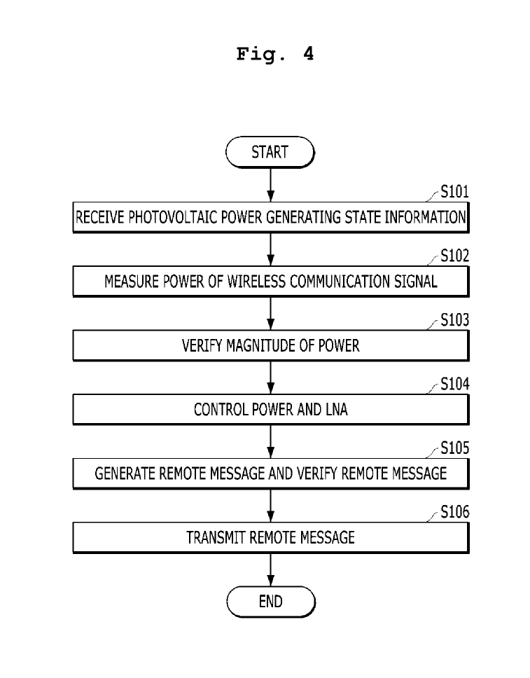

FIG. 4 is a flowchart illustrating a photovoltaic power generation monitoring method according to an exemplary embodiment.

In performing a photovoltaic power generation monitoring method of an RTU, a wireless RTU device receives photovoltaic power generation information from a photovoltaic inverter via a ZigBee communications in operation S101. According to an exemplary embodiment, the RTU may receive the photovoltaic power generation state information from a plurality of photovoltaic inverters via a ZigBee communication.

In addition, in operation S102, the RTU measures the power of a ZigBee wireless communications signal through which the photovoltaic power generation state information is received.

In addition, in operation S103, the RTU determines whether the measured power belongs to a normal range.

In addition, in operation S104, the RTU performs transmit power control and LNA control on the basis of the determination result. According to an exemplary embodiment, when the RTU receives the photovoltaic power generation state information from a plurality of photovoltaic inverters via a ZigBee communication, and in a case in which the ZigBee communications with one of the plurality of photovoltaic inverters does not perform, the RTU may control at least one of transmit power and LNA to thereby determine whether the ZigBee communications that does not perform performs again. To determine whether the ZigBee communications that does not perform performs again, the RTU switches an LNA ON/OFF state, and subsequent to the switching, may determine, again, whether the ZigBee communications performs.

In addition, in operation S105, the RTU generates a remote message on the basis of the received photovoltaic power generation state information, and verifies a presence of an error in the generated remote message. The remote message may include power of a wireless communications signal, an inverter wireless communications error, and an operation temperature sensor value.

In operation S106, in a case in which the error is absent on the basis of the verification result, the RTU transmits the generated remote message to a monitoring server via a Wi-Fi communication. In other words, the RTU may use the Internet network connected to a Wi-Fi communications network.

In addition, according to an exemplary embodiment, the monitoring method may further include reading external temperature of the RTU, and the generating of the remote message may include performing temperature compensation for the received photovoltaic power generation state information on the basis of the read internal temperature of the RTU. In other words, even when a measured value is affected by temperature, the measured value may be compensated again such that an accurate value may be transmitted to the monitoring server.

In addition, according to an exemplary embodiment, the monitoring method may further include receiving at least one of a feedback message and an RTU control message from the monitoring server. A description pertaining to the messages will be described in greater detail later with reference to FIGS. 6 and 7.

The monitoring server may verify a remote message transmitted from an RTU. In other words, the monitoring server may compare whether all data included the remote message has a normal value with pre-stored data to thereby determine whether the RTU and the photovoltaic inverter operate in a normal state, and accordingly, may transmit a feedback message or a control message to the wireless RTU device again.

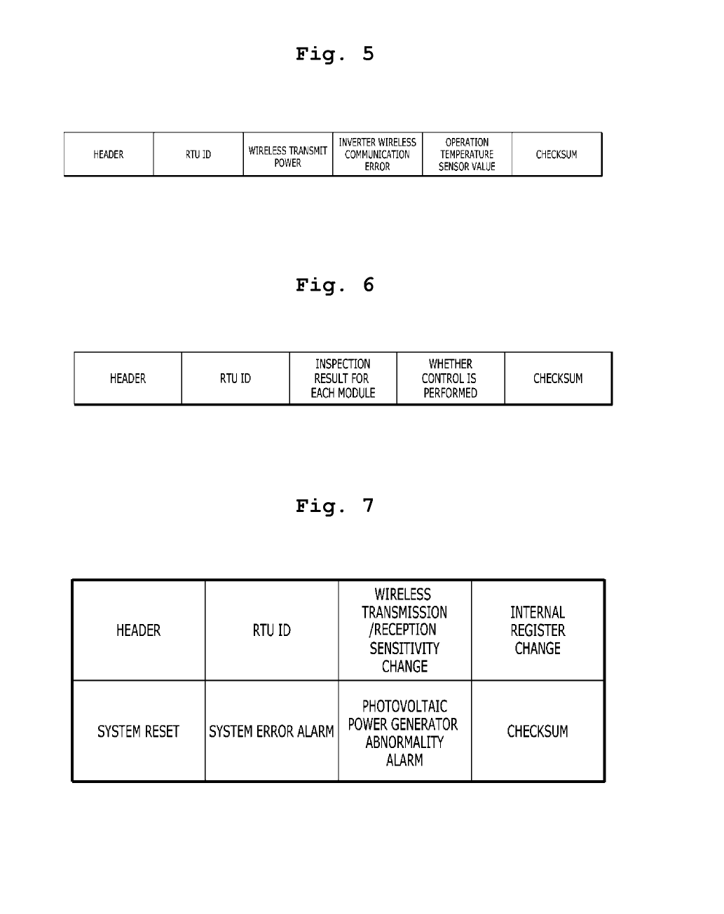

FIG. 5 is a diagram illustrating a remote message according to an exemplary embodiment.

According to an exemplary embodiment, a remote message may include a header, an RTU identification (“ID”), wireless transmit power, an inverter wireless communications error, an operation temperature sensor value, and a checksum.

The header may include information for recognizing the remote message.

The RTU ID may include information for determining one of plurality RTUs from which a remote message is transmitted.

The wireless transmit power may include data (e.g., power magnitude) associated with the power of a ZigBee communications signal received from the RTU.

The inverter wireless communications error may include data associated with whether data from the inverter of the photovoltaic power plant operates in a normal state.

The operation temperature sensor value may include a value of an ambient temperature of the wireless RTU device.

The checksum may include data for determining whether all the data values included in the remote message are included.

FIG. 6 is a diagram illustrating a configuration of a feedback message transmitted from a monitoring server to an RTU according to an exemplary embodiment.

According to an exemplary embodiment, the feedback message may include a header, an RTU ID, an inspection result for each module, whether control is performed, and a checksum.

The header may include information for recognizing a feedback message.

The RTU ID may include information for determining one of a plurality of RTUs to which transmission is performed.

Whether control is performed may include data associated with whether the control of the RTU is required. In other words, for example, an RTU that receives a feedback message having a whether control is performed value of ‘1’ may wait to receive an additional RTU control message.

The checksum may include data for determining whether all data values included in the feedback message are included.

FIG. 7 is a diagram illustrating a configuration of a control message transmitted from a monitoring server to an RTU according to an exemplary embodiment.

According to an exemplary embodiment, the RTU control message may include a header, an RTU ID, a wireless transmission/reception sensitivity change, an internal register change, a system reset, a system error alarm, a photovoltaic power generator abnormality alarm, and a checksum.

The header may include information for recognizing a control message.

The RTU ID may include information for determining one of a plurality of RTUs to which transmission is performed.

The wireless transmission/reception sensitivity change may include a control value for changing a wireless transmission/reception sensitivity between the RTU and the photovoltaic power plant. In other words, the magnitude of wireless transmission/reception via the monitoring server may be controlled.

The internal register change may include a control value for changing a value recorded in an internal register of the RTU.

The system reset may include a control value for resetting the RTU.

The system error alarm may include a control value for transmitting an error alarm to the RTU.

The photovoltaic power generator abnormality alarm may include a control value for transmitting an abnormality alarm to a photovoltaic power generator connected to the RTU.

The checksum may include data for determining whether all data values included in a control message are included.

Although a few embodiments of the present invention have been shown and described, the present invention is not limited to the described embodiments. Instead, it would be appreciated by those skilled in the art that changes may be made to these embodiments without departing from the principles and spirit of the invention, the scope of which is defined by the claims and their equivalents.

1. A method for monitoring photovoltaic power generation using remote terminal unit (RTU) comprising:
receiving photovoltaic power generation state information via ZigBee wireless communications from a photovoltaic inverter;
measuring the power of ZigBee wireless communications signals through which the photovoltaic power generation state information is received;
determining whether the measured power is within a normal range;
performing transmission power control and low-noise amplifier (LNA) control on the basis of the determination result;
generating remote message on the basis of the received photovoltaic power generation state information;
verifying the presence of errors in the generated remote message; and
transmitting the generated remote message to a monitoring server via Wi-Fi communications in absence of the errors on the basis of the verification result.

2. The method of claim 1, further comprising:
reading external temperature of the RTU, wherein the generating of the remote message comprises performing temperature compensation for the received photovoltaic power generation state information on the basis of the read external temperature of the RTU.

3. The method of claim 1, wherein the receiving of the photovoltaic power generation state information comprises receiving the photovoltaic power generation state information via the ZigBee wireless communications from a plurality of photovoltaic inverters.

4. The method of claim 3, wherein the receiving of the photovoltaic power generation state information further comprises, in a case where the ZigBee wireless communications with one of the plurality of photovoltaic inverters is disconnected:
performing at least one of the transmission power control and the LNA control; and
determining whether the disconnected ZigBee communications is established again.

5. The method of claim 4, wherein the determining whether the disconnected ZigBee communications is established again comprises:
switching LNA ON/OFF state; and
determining the disconnected ZigBee communications is established again.

6. The method of claim 1, wherein the remote message comprises the power of wireless communications signals, wireless communications errors of the photovoltaic inverter, and value of operation temperature sensor.

7. The method of claim 1, further comprising receiving at least one of a feedback message and an RTU control message from the monitoring server.

8. A wireless remote terminal unit (RTU) device for monitoring photovoltaic power generation comprising:
a ZigBee wireless communications unit for receiving photovoltaic power generation state information via ZigBee wireless communications from a photovoltaic inverter;
a power measuring unit for measuring the power of ZigBee wireless communications signals through which the photovoltaic power generation state information is received;
a measured power determining unit for determining whether the measured power is within a normal range;
a controlling unit for performing transmission power control and low-noise amplifier (LNA) control on the basis of the determination result;
a message generating unit for generating a remote message on the basis of the received photovoltaic power generation state information;
a verifying unit for verifying the presence of errors in the generated remote message; and
a Wi-Fi communications unit for transmitting the generated remote message to a monitoring server via Wi-Fi communications in absence of the errors on the basis of the verification result.

9. The wireless RTU device of claim 8, further comprising a temperature sensor for reading an external temperature of the RTU, wherein the message generating unit performs temperature compensation for the received photovoltaic power generation state information on the basis of the read external temperature of the RTU.

10. The wireless RTU device of claim 8, wherein the ZigBee wireless communications unit receives the photovoltaic power generation state information via the ZigBee wireless communications from a plurality of photovoltaic inverters.

11. The wireless RTU device of claim 10, wherein in a case where the ZigBee wireless communications with one of the plurality of photovoltaic inverters is disconnected, the controlling unit controls at least one of the transmission power control and the LNA control and determines whether the disconnected ZigBee wireless communications is established again.

12. The wireless RTU device of claim 11, wherein the controlling unit switches an LNA ON/OFF state and determines whether the disconnected ZigBee wireless communications is established again after switching.

13. The wireless RTU device of claim 8, wherein the remote message comprises the power of wireless communications signals, wireless communications errors of the photovoltaic inverter, and value of operation temperature sensor.

14. The wireless RTU device of claim 8, wherein the Wi-Fi communications unit receives at least one of a feedback message and an RTU control message from the monitoring server.

15. An integrated ZigBee wireless communications module, comprising:
a ZigBee wireless communications unit for receiving photovoltaic power generation state information via ZigBee wireless communications from a photovoltaic inverter;
a power measuring unit for measuring the power of ZigBee wireless communications signals through which the photovoltaic power generation state information is received;
a measured power determining unit for determining whether the measured power is within a normal range;
a temperature sensor for reading an external temperature of the integrated ZigBee communications module; and
an information transmitting unit for transmitting information output from the temperature sensor and the measured power determining unit to a wireless remote terminal unit (RTU).

16. The module of claim 15, wherein the ZigBee wireless communications unit receives the photovoltaic power generation state information via ZigBee communications from a plurality of photovoltaic inverters.

17. The module of claim 15, wherein the measured power determining unit comprises information associated with a predetermined normal range of the power that is renewed according to an update signal input from a network.
